(19) United States
(12) Patent Application Publication
(10) Pub. No.: US 2026/0197958 A1
(43) Pub. Date: Jul. 9, 2026

(54) CONTROL DEVICE ARRANGEMENT WITH HEAT TRANSFER MATERIAL ARRANGED IN A CHANNEL SYSTEM OF A CIRCUIT BOARD UNIT AND METHOD FOR PRODUCING A CONTROL DEVICE ARRANGEMENT

(71) Applicant: CONNAUGHT ELECTRONICS Ltd., Tuam (IE)

(72) Inventors: Ramon Casagrande, Tuam (IE); Brian Cleary, Tuam (IE)

(73) Assignee: CONNAUGHT ELECTRONICS Ltd., Tuam (IE)

(21) Appl. No.: 18/865,528

(22) PCT Filed: May 11, 2023
(86) PCT No.: PCT/EP2023/062540

§ 371 Date: Nov. 13, 2024

(30) Foreign Application Priority Data
May 13, 2022 (DE) 10 2022 112 003.1

(51) Int. Cl. H05K 7/14; H05K 7/20

(52) U.S. Cl. CPC H05K 7/1427; H05K 7/20254; H05K 7/20272

(57) ABSTRACT

A control device arrangement with a housing, in which at least one circuit board unit and at least one cooling device are arranged. The at least one cooling device is supplied with a cooling fluid in the cooling operation and formed for dissipating heat from the at least one circuit board unit. The at least one circuit board unit is thermally coupled to the at least one cooling device by a heat transfer material. The circuit board unit includes an outer wall facing the cooling device, in which at least one recess is formed. The heat transfer material is arranged in the at least one recess. Furthermore, the invention relates to a method for producing such a control device arrangement.

The invention relates to a control device arrangement with a housing, in which at least one circuit board unit and at least one cooling device are arranged. The at least one cooling device is supplied with a cooling fluid in the cooling operation and formed for dissipating heat from the at least one circuit board unit. The at least one circuit board unit is thermally coupled to the at least one cooling device by means of a heat transfer material. Furthermore, the invention relates to a method for producing such a control device arrangement.

The use of a heat transfer material between a circuit board and respective heat sinks, which are arranged on sides of the circuit board opposing each other, is for example disclosed in U.S. Pat. No. 7,609,523B1.

Furthermore, US 2014/0084449 A1 describes a semiconductor package with a structuring on the rear side, which faces a heat sink. The structuring is to effect a better distribution of a heat conducting paste applied onto the heat sink when the semiconductor package is screwed to the heat sink.

It is an object of the present invention to provide a control device arrangement of the initially mentioned type, in which an improved heat dissipation from the circuit board unit is achievable, and to specify a method for producing such a control device arrangement.

This object is solved by a control device arrangement having the features of claim 1 and by a method having the features of claim 15. Advantageous configurations with convenient developments of the invention are specified in the dependent claims and in the following description.

The control device arrangement according to the invention includes a housing, in which at least one circuit board unit and at least one cooling device are arranged. The at least one cooling device is supplied with a cooling fluid in the cooling operation and formed for dissipating heat from the at least one circuit board unit. The at least one circuit board unit is thermally coupled to the at least one cooling device by means of a heat transfer material. The circuit board unit comprises an outer wall facing the cooling device, in which at least one recess is formed. The heat transfer material is arranged in the at least one recess.

Due to the provision of the heat transfer material, a particularly efficient heat dissipation from the circuit board unit towards the cooling device can be achieved, wherein the heat is in turn dissipated from the cooling device by means of the cooling fluid in the cooling operation of the cooling device. This is based on the realization that a less efficient heat transfer from the circuit board unit to the cooling device is achievable in particular with formation of the outer wall of the circuit board unit of metal and formation of an outer wall of the cooling device of metal than it is the case due to the provision of the heat transfer material.

In addition, by providing the at least one recess in the outer wall of the circuit board unit, the heat transfer material can be arranged exactly where it is particularly beneficial with regard to heat release of the circuit board unit in the operation of the same. In that the heat transfer material at least largely fills the at least one recess, a correct positioning of the heat transfer material in relation to the circuit board unit is additionally ensured. Thereby, a formation of undesirably hot spots on the circuit board unit in the operation of the circuit board unit can in particular be prevented. This is conducive to a permanently high functionality of the circuit board unit.

The efficient heat dissipation from the at least one circuit board unit is in particular advantageous if the control device arrangement is for example employed in a vehicle, in which the at least one circuit board unit or multiple circuit board units are constituents of one or more electronic control devices or electronic control units of the vehicle.

Thus, the circumstance can in particular be taken into account that a plurality of electronic control devices or electronic control units is usually to be provided in a vehicle such as an autonomously driving vehicle and/or an electrically, in particular purely electrically, driven vehicle. Herein, the control devices can in particular take over tasks of at least one driver assistance function of the vehicle. The arrangement of the circuit board units preferably formed as components of such control devices for a vehicle in the housing of the control device arrangement is advantageous. Because the circuit board units are then accommodated in the housing in a very compact and installation space saving and yet well accessible manner. This is particularly advantageous when the control device arrangement is used in the vehicle. The invention therefore preferably also relates to a vehicle, in particular a motor vehicle, with the control device arrangement.

In particular, the outer wall can be a part of a shell or at least one-sided, preferably at least top-side and bottom-side, cover of the circuit board unit, wherein at least one circuit board of the circuit board unit is received within this shell. In particular with formation of the shell or cover of the circuit board unit of a sheet metal, the heat transfer material ensures a good heat transfer from the circuit board unit to the cooling device. This in particular applies if a corresponding wall of the cooling device is also formed of metal.

Preferably, the heat transfer material is introduced into the at least one recess via an inlet opening, which is accessible from a narrow side of the circuit board unit in an installation position of the circuit board unit in the housing. Thus, an at least large filling of the at least one recess with the heat transfer material can be achieved even with constricted space conditions and in a procedurally simple manner. In addition, the introduction of the heat transfer material via the inlet opening into the at least one recess is possible while both the circuit board unit and the cooling device are already arranged in the housing. This can be particularly simply realized in terms of manufacture, in particular if the heat transfer material is formed as a heat conducting paste. Because such a heat conducting paste has sufficient flowability to be introduced into the at least one recess from the narrow side of the circuit board unit via the inlet opening.

Preferably, the at least one recess is formed as a channel system, which includes at least one channel section, which is connected to at least one basin area of the channel system. Herein, the at least one basin area has a larger width than the at least one channel section of the channel system. By the formation of the at least one recess as such a channel system, it can be very productively ensured that in the operation of the circuit board unit and the cooling device, the heat is there dissipated from the circuit board unit where it is advantageous for preventing the occurrence of hot spots. Thus, an operation of the control device arrangement can in particular be ensured, in which overheatings of the circuit board unit are permanently avoided.

Preferably, the channel system includes a plurality of basin areas, wherein the basin areas are connected to each other via respective channel sections. Thus, for instance in producing the control device arrangement, a purposeful positioning of the heat transfer material in the basin areas can be achieved, which is advantageous with regard to the improved dissipation of heat from the circuit board unit.

The basin areas can have a larger depth than the at least one channel section. In this manner, it can be achieved that particularly much heat transfer material is available in the basin areas for the heat dissipation towards the cooling device.

Additionally or alternatively, respective basin areas can have depths different from each other. By the depth of the respective basin area, it can in particular be ensured that a particularly good thermal coupling to the cooling device via the heat transfer material is achieved at predetermined locations of the circuit board unit. This is conducive to the improved heat dissipation from the circuit board unit.

Preferably, the basin areas are formed in sections of the circuit board unit, in which more heat is released in the operation of the circuit board unit than in areas of the circuit board unit adjoining to the sections. In this manner, it is ensured that undesired overheating does not occur in these sections of the circuit board unit releasing more heat in the operation of the circuit board unit. This is advantageous for a robust operation of the circuit board unit.

Preferably, the channel system comprises at least one air outlet opening. Herein, in a state, in which the at least one circuit board unit and the at least one cooling device are arranged in the housing of the control device arrangement, expelling of air from the channel system via the at least one air outlet opening can be effected due to introduction of the heat transfer material into the channel system. In this manner, a very large filling of the channel system with the heat transfer material can be achieved.

Preferably, the at least one air outlet opening opens into a narrow side of the circuit board unit. Because the air displaced or expelled out of the channel system can be particularly simply discharged into the environment of the circuit board unit from the narrow side of the circuit board unit, while the heat transfer material is introduced into the channel system.

The circuit board unit can comprise a first area with a first thickness and a second area with a second thickness, wherein the second thickness is larger than the first thickness. Herein, the at least one recess is formed in the first area. Due to the lower thickness of the circuit board unit in the first area, the heat released in the operation of the circuit board unit can get towards the outer wall in a particularly fast and unimpeded manner, in which the at least one recess is formed. In particular if components of the circuit board unit releasing comparatively much heat in the operation are arranged in the first area of the circuit board unit, a particularly good heat dissipation from these components via the heat transfer material towards the cooling device can be ensured by providing the at least one recess in the first area. This too, is advantageous for a permanently robust operation of the circuit board unit.

In particular, it can be provided that the at least one recess is only formed in the first area and that the second area is free of such recesses, respectively. Herein, it can in particular be provided that no or less components of the circuit board unit releasing comparatively much heat in the operation are arranged in the second area having the larger thickness than in the first area.

In contrast, a particularly good accessibility to the circuit board unit, in particular to connecting elements of the circuit board unit, can be ensured in the second area. In particular, an end side of the second area facing away from the cooling device can be accessible for such purposes via an access opening formed in the housing of the control device arrangement.

Preferably, an end side of the second area adjoining to the first area faces a narrow side of the cooling device. Thereby, the circuit board unit L-shaped in cross-section particularly largely encloses the cooling device. This is advantageous with regard to an efficient dissipation of heat from the circuit board unit by means of the cooling device.

Preferably, the control device arrangement comprises at least two circuit board units, which are arranged mirror-imaged to each other in the housing. Herein, respective outer walls, comprising the at least one recess, of the circuit board units arranged mirror-imaged face the same cooling device. Thus, heat can be particularly efficiently dissipated from even two circuit board units by means of the cooling device arranged between the outer walls of the circuit board units. This is conducive to a compact construction of the control device arrangement.

Preferably, at least two cooling devices are arranged in the housing, which are formed as cooling plates. Herein, a respective cooling plate is received between two circuit board units in a sandwich-like construction. In this manner, at least three, preferably four circuit board units of the control device arrangement can be very efficiently cooled by means of two cooling plates.

Preferably, the cooling fluid is passed through the at least one cooling device in the cooling operation of the cooling device. Thus, the cooling fluid can ensure a particularly efficient heat dissipation from the cooling device. For example, the cooling device can comprise a coolant inlet and a coolant outlet. By introducing the cooling fluid, preferably in the form of a liquid coolant, via the coolant inlet into the cooling device and discharging the cooling fluid or coolant from the cooling device via the coolant outlet, cooling of the at least one circuit board unit can be effected in the cooling operation. Due to the cooling device being passed by the cooling fluid, in particular by the liquid coolant, a very good heat absorption by the at least one cooling device can be achieved.

In the housing, a plurality of circuit board units can be arranged above each other in a vertical direction of the housing. Herein, the circuit board units arranged above each other in the vertical direction are connected to a further circuit board by means of a respective connecting element. The further circuit board is arranged on a rear side of the housing, wherein the rear side is opposing a front-side access opening of the housing. In this manner, by introducing the circuit board units into the housing, the connection of the circuit board units to the further circuit board can be realized at the same time. This is advantageous with regard to simplified mounting of the control device arrangement. In particular, the further circuit board can be formed as a main circuit board of the control device arrangement.

Preferably, the circuit board unit is applied with a pressure directed towards the cooling device by means of at least one spring element. Thus, a particularly intimate abutment of the circuit board unit on the heat transfer material can be achieved.

This in particular applies if the pressure acts in the area of the heat transfer material. Because by a purposeful application of the circuit board unit with the pressure in the area of the heat transfer material, a very good thermal coupling of the circuit board unit to the cooling device via the heat transfer material can be achieved. Furthermore, irregularities for instance with regard to flatness of a bearing surface as well as roughness of surfaces and additionally irregularities caused by manufacturing tolerances can be well compensated for by applying the circuit board unit with the pressure in the area of the heat transfer material.

The heat transfer material applied with the pressure by means of the spring element can in particular be formed as a heat conducting pad. Then, the heat transfer material can be particularly well handled, in particular in the manufacture or production of the control device arrangement. Such a heat conducting pad can be arranged in the area of the at least one recess in producing the control device arrangement to achieve a purposeful heat dissipation from predetermined areas of the circuit board unit.

Preferably, the circuit board unit comprises at least one stud element, which cooperates with a guide rail provided on the side of the housing. Herein, the at least one stud element is guided along the guide rail in introducing the circuit board unit into the housing. Thereby, mounting, thus introducing the circuit board unit into the housing, proves to be particularly simple and process-reliable.

The stud element can rest on a bar-like guide rail or engage with a guide rail formed in the manner of a groove in cross-section to cooperate with the guide rail. When the stud element engages with the guide rail, thus, a particularly precise guide of the at least one circuit board unit in introducing into the housing of the control device arrangement is achievable.

Preferably, the stud element is applied with the pressure by means of the spring element. Thus, the pressure can be very purposefully exerted on the circuit board unit.

Preferably, the guide rail comprises a recess formed towards the cooling device in the area of a target position of the stud element. Herein, the stud element is received in the recess. Due to the provision of the recess for example formed in the manner of a locking depression in the guide rail, a particularly large movement or displacement of the circuit board unit towards the cooling device can be effected upon applying the stud element with the pressure. This is advantageous for a good heat transfer effected by the heat transfer material from the circuit board unit to the cooling device.

Preferably, the at least one spring element is fixed to the housing, wherein the at least one spring element includes a leg, which applies the stud element with the pressure acting towards the cooling device due to the introduction of the circuit board unit into the housing along the guide rail. Thus, a targeted pressure application to the stud element can be achieved with simple construction and simple arrangement of the spring element.

Preferably, the circuit board unit comprises a plurality of stud elements, wherein each of the stud elements is applied with the pressure acting towards the cooling device by a spring element acting on it. Thus, an advantageous distribution of the contact pressure can be achieved, which ensures the intimate contact of the circuit board unit and the cooling device with the heat transfer material. In addition, the spring force of the respective spring element can thus be very largely exploited.

In the method according to the invention for producing a control device arrangement, at least one circuit board unit and at least one cooling device are arranged in a housing of the control device arrangement. The at least one cooling device is supplied with a cooling fluid in the cooling operation and formed for dissipating heat from the at least one circuit board unit. The at least one circuit board unit is thermally coupled to the at least one cooling device by means of a heat transfer material. The circuit board unit comprises an outer wall facing the cooling device, in which at least one recess is formed. The heat transfer material is arranged in the at least one recess. By the heat transfer material effecting the thermal coupling of the circuit board unit to the cooling device, an improved heat dissipation from the circuit board unit is achievable.

In particular, the heat transfer material can be arranged in the at least one recess, while the at least one circuit board unit and the at least one cooling device are already arranged in the housing. This is advantageous with regard to a simple and low-effort production of the control device arrangement. In this manner, it can in particular be ensured that at least a majority of the heat transfer material remains in the at least one recess and is not moved out of a predetermined position due to a movement of the circuit board unit in relation to the cooling device.

The advantages and preferred embodiments described for the control device arrangement according to the invention also apply to the method according to the invention and vice versa.

The features and feature combinations mentioned above in the description as well as the features and feature combinations mentioned below in the description of figures and/or shown in the figures alone are usable not only in the respectively specified combination, but also in other combinations without departing from the scope of the invention. Thus, implementations are also to be considered as encompassed and disclosed by the invention, which are not explicitly shown in the figures and explained, but arise from and can be generated by separated feature combinations from the explained implementations. Implementations and feature combinations are also to be considered as disclosed, which thus do not comprise all of the features of an originally formulated independent claim. Moreover, implementations and feature combinations are to be considered as disclosed, in particular by the implementations set out above, which extend beyond or deviate from the feature combinations set out in the relations of the claims.

Further features of the invention are apparent from the claims, the figures and the description of figures. There show:

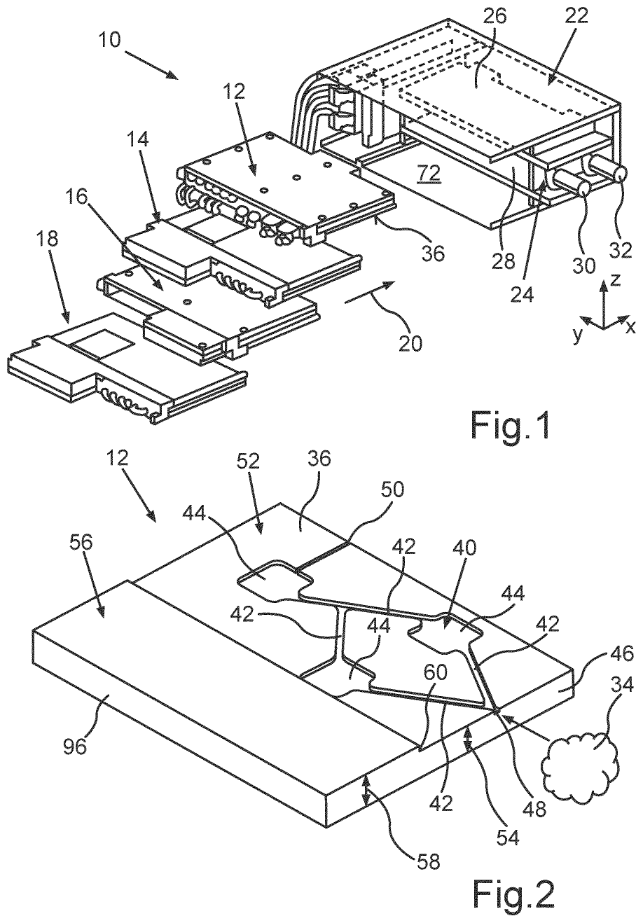

FIG. 1 in a schematic perspective view, a control device arrangement with a housing, in which two cooling devices formed as cooling plates are arranged, which are passed by a coolant in the cooling operation, wherein four circuit board units are additionally shown before their installation in the housing;

FIG. 2 schematically one of the circuit board units L-shaped in cross-section, which comprises an outer wall facing the cooling device, wherein the outer wall is a constituent of a shell or a circuit board housing of the circuit board unit;

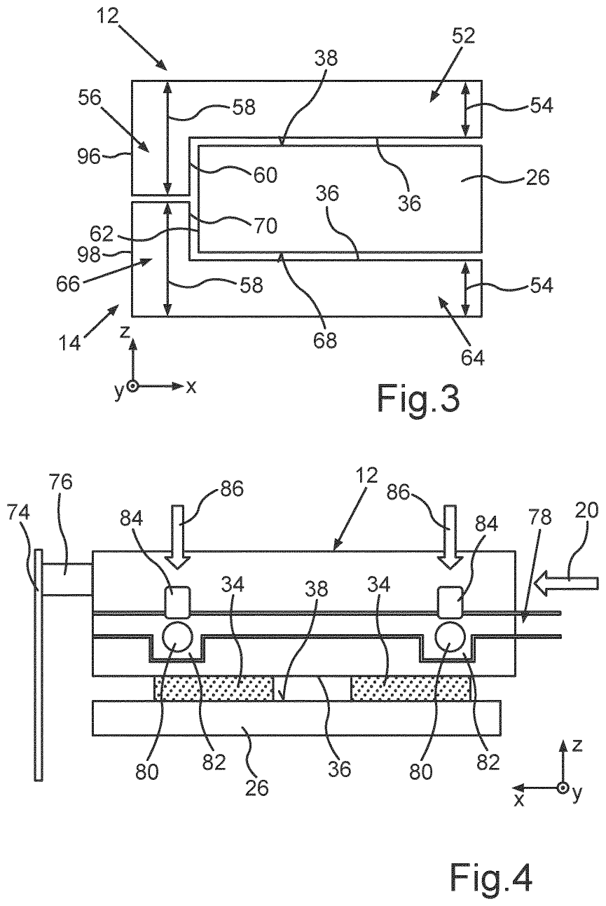

FIG. 3 severely schematized two of the circuit board units L-shaped in cross-section according to FIG. 2 and the arrangement thereof in relation to one of the two cooling devices formed as cooling plates of the control device arrangement in the housing;

FIG. 4 schematically the application of a spring force to stud elements of one of the circuit board units, wherein the spring force ensures pressing the circuit board unit onto a heat transfer material, which is arranged between the circuit board unit and the cooling plate;

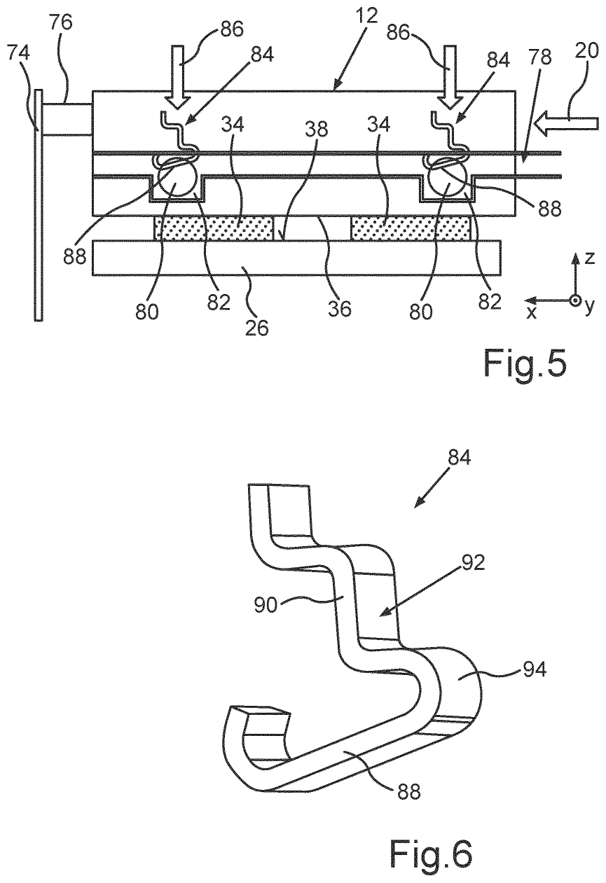

FIG. 5 schematically a possible configuration of compression springs applying the spring force to the stud elements; and

FIG. 6 one of the compression springs according to FIG. 5 in a perspective view.

In the figures, identical or functionally identical elements are provided with identical reference characters.

FIG. 1 schematically shows components of a control device arrangement 10 in a non-assembled state. The control device arrangement 10 includes a plurality of circuit board units 12, 14, 16, 18. The individual circuit board units 12, 14, 16, 18 can be introduced into or installed in a housing 22 of the control device arrangement 10 in a mounting direction 20, which is illustrated by an arrow in FIG. 1.

In the housing, a cooling system 24 is arranged, which presently includes a first cooling device 26 and a second cooling device 28. The first cooling device 26 and the second cooling device 28 are for example formed as cooling plates in particular formed of metal, which are passed by a cooling fluid preferably in the form of a liquid coolant in the cooling operation. For this purpose, the cooling system 24 comprises a coolant inlet 30 and a coolant outlet 32.

The respective circuit board units 12, 14, 16, 18 include a shell presently formed of a sheet metal or a circuit board housing. Outer walls of the respective circuit board unit 12, 14, 16, 18 are formed by this shell or by this circuit board housing.

In FIG. 2, the circuit board unit 12, which is the upper one according to FIG. 1, is exemplarily and schematically shown. However, the explanations made for the circuit board unit 12 shown in FIG. 2 apply in an analogous manner to the further circuit board units 14, 16, 18.

Within the shell, the circuit board unit 12 comprises at least one circuit board (presently not shown for reasons of simplicity), by which a control device can be provided, or which can be a part of a control device. In that a plurality of circuit board units 12, 14, 16, 18 is accommodated in the housing 22, a plurality of control devices can be provided by the control device arrangement 10, wherein the respective control devices or electronic control units can for example be formed for performing control tasks of a driver assistance system of a vehicle.

It is of importance to dissipate the heat generated in the operation of the circuit board units 12, 14, 16, 18 from the circuit board units 12, 14, 16, 18. For this purpose, the respective circuit board unit 12, 14, 16, 18 is thermally coupled to one of the two cooling devices 26, 28 via a heat transfer material 34 (see FIG. 4). In FIG. 2, the heat transfer material 34 is schematically shown, before the heat transfer material 34 is located in the position intended for it or in the positions intended for it.

The procedure of bringing the heat transfer material 34 in particular formed as a heat conducting paste into the positions intended for the heat transfer material 34 between the respective circuit board unit 12, 14, 16, 18 and one of the two cooling devices 26, 28 is to be explained with reference to FIG. 2.

In FIG. 2, an outer wall 36 of the shell or of the circuit board housing is shown of the circuit board unit 12 shown in FIG. 2, wherein the outer wall 36 faces one of the cooling devices 26, 28, for example the cooling device 26, which is the upper one in vertical direction z of the housing 22 according to FIG. 1. The vertical direction z, a transverse direction y of the housing 22 as well as a depth direction x of the housing 22 are illustrated by a coordinate system in FIG. 1. The arrangement of the circuit board unit 12 in relation to the cooling device 26 in the housing 22 is also schematically shown in FIG. 3.

It is apparent in particular from the view in FIG. 3 how the outer wall 36 seen in FIG. 2 faces a top side 38 of the cooling device 26. In this outer wall 36 of the circuit board unit 12 facing the cooling device 26, at least one recess is formed, in which the heat transfer material 34 is arranged when the circuit board unit 12 and the cooling device 26 associated with this circuit board unit 12 are arranged in the housing 22.

According to FIG. 2, the at least one recess is formed as a channel system 40, which includes a plurality of channel sections 42 and a plurality of basin areas 44. The basin areas 44 of the channel system 40 are connected to each other via the channel sections 42. Herein, the basin areas 44 each have a larger width than the channel sections 42.

The arrangement of the basin areas 44 and the channel sections 42 shown in FIG. 2 is only schematic and exemplary. Accordingly, a network of channel sections 42 and basin areas 44 can also be formed in the outer wall 36, which faces the cooling device 26, in a manner other than exemplarily shown in FIG. 2. In variants of the circuit board unit 12, the shapes of the basin areas 44 can also deviate from the presently exemplarily shown, substantially square or rectangular shapings. Preferably, the basin areas 44 are formed where particularly much heat is released from electronic parts or the like components arranged on the circuit board in the operation of the circuit board unit 12.

In variants of the respective circuit board unit 12, 14, 16, 18, a depth of the channel sections 42 and/or of the basin areas 44 can deviate from the depth of these components of the channel system 40 exemplarily shown in FIG. 2. Furthermore, channel sections 42 different from each other and/or basin areas 44 different from each other can also each have different depths or depths different from each other.

According to FIG. 2, an inlet opening 48 is formed on a narrow side 46 of the circuit board unit 12, which is accessible when the circuit board unit 12 is installed in the housing 22 of the control device arrangement 10, wherein the outer wall 36 faces the top side 38 of the cooling device 26 in this installation position of the circuit board unit 12 (see FIG. 3). Therefore, in this state of the control device arrangement 10, in which both the at least one circuit board unit 12, 14, 16, 18 and the at least one cooling device 26, 28 are arranged in the housing 22 of the control device arrangement 10, the heat transfer material 34 can be introduced into the at least one recess presently in the form of the channel system 40 via the inlet opening 48.

For this purpose, the heat transfer material 34 is preferably formed as a flowable heat conducting paste, which moves along in the channel sections 42 and at least largely fills up or fills the channel sections 42 and the basin areas 44 on the way to an air outlet opening 50. Air can be expelled out of the channel system 40 via the air outlet opening 50, while the heat transfer material 34 is introduced into the channel system 40.

In the variant of the circuit board unit 12 exemplarily shown in FIG. 2, the circuit board unit 12 has an L-shape in cross-section, which is also well apparent from the schematic representation in FIG. 3. Herein, the circuit board unit 12 includes a first area 52 with a first thickness 54 and a second area 56 with a second thickness 58. Herein, the second thickness 58 is larger than the first thickness 54. According to FIG. 2, the channel system 40 is only formed in the first area 52, which has the lower thickness 54.

Due to this stepped configuration of the circuit board unit 12, the second area 56 includes an end side 60 formed in the area of the step or the transition to the first area 52 (see FIG. 3), which faces a narrow side 62 of the cooling device 26 in the state of the circuit board unit 12 installed in the housing 22 of the control device arrangement 10 (see FIG. 3). Thus, heat can be well dissipated towards the cooling device 26 via this end side 60 of the circuit board unit 12 too.

Preferably, no or less components of the circuit board, which provide a severe heat release in the operation of the circuit board, are arranged in the second area 56, which has the second, larger thickness 58. Then, it is in particular sufficient to provide the at least one recess presently provided by the channel system 40 in the outer wall 36 only in the first area 52 of the circuit board unit 12.

In FIG. 3, it is schematically shown how a further one of the circuit board units 12, 14, 16, 18, for example the second circuit board unit 14, can be cooled by means of the same cooling device 26. For example, the second circuit board unit 14 can be arranged mirror-imaged to the first circuit board unit 12 in the housing 22, which is not shown in more detail for reasons of clarity in FIG. 3. The second circuit board unit 14 too, has the L-shape in cross-section, thus a first area 64 with the first, lower thickness 54 and a second area 66 with the second, larger thickness 58. Herein, the outer wall 36 of the second circuit board unit 14 faces a bottom side 68 of the cooling device 26.

And in analogous manner as explained for the first circuit board unit 12, in this mirror-imaged arrangement of the circuit board units 12, 14 in the housing 22, an end side 70 of the second area 66 of the second circuit board unit 14, which adjoins to the first area 64 of the second circuit board unit 14, faces the narrow side 62 of the cooling device 26.

In analogous manner as explained for the circuit board units 12, 14 shown in FIG. 3, the two further circuit board units 16, 18 can be arranged mirror-imaged to each other in the housing 22 such that the cooling device 28, which is the lower one according to FIG. 1, is received between the two further circuit board units 16, 18 in a sandwich-like construction.

Outer end sides 96, 98, far from the respective first area 52, 64, of the second areas 56, 66 of the circuit board units 12, 14 are well accessible from a front-side access opening 72 (see FIG. 1) of the housing 22. The same applies to the end sides of the further circuit board units 16, 18 accessible via this access opening 72. This is advantageous, for instance to gain access to connecting elements (presently not shown in more detail) of the respective circuit board unit 12, 14, 16, 18.

In FIG. 1 and in FIG. 4, it is schematically shown how the respective circuit board unit 12 can be introduced into the housing 22 in the mounting direction 20, which can for example correspond to the depth direction x of the housing 22. In the area of a rear side of the housing 22, which is opposing the front-side access opening 72, the respective circuit board unit 12, 14, 16, 18 can be connected to a further circuit board 74, which is schematically shown in FIG. 4. For connecting to this further circuit board 74, the respective circuit board unit 12, 14, 16, 18 can comprise a rear connecting element 76, which is also only schematically shown in FIG. 4.

In order to facilitate the introduction of the respective circuit board unit 12, 14, 16, 18 into the housing 22 (not shown in FIG. 4), guide rails 78 can be provided on the side of the housing 22 (see FIG. 4). For example, the guide rails 78 can be formed on sidewalls of the housing 22, which are opposing each other in transverse direction y of the housing 22 (see FIG. 1).

According to FIG. 4, respective stud elements 80 can protrude from the respective circuit board unit 12 in the transverse direction y, which are formed in the manner of guide studs and are moved in the mounting direction 20 along the guide rails 78 to take the circuit board unit 12 into its installation position or mounting position within the housing 22. As is apparent from FIG. 4, these stud elements 80 presently engage with the respective guide rail 78.

When the circuit board unit 12 and the stud elements 80 together with it have reached their target position or intended installation position in the housing 22, thus, the stud elements 80 are in the area of recesses 82, which are formed in the guide rails 78. Furthermore, respective portions of the heat transfer material 34 are schematically shown in FIG. 4, which ensure the thermal coupling of the circuit board unit 12 to the cooling device 26. The respective areas with the heat transfer material 34 according to FIG. 4 can be formed as heat conducting pads, in particular as heat conducting pads separate from each other or connected to each other.

Preferably, spring elements 84, which are only indicated with regard to their positioning on the housing 22 in FIG. 4, apply the respective stud elements 80 with a pressure, which is directed towards the cooling device 26 and which is illustrated by respective arrows 86 in FIG. 4. Accordingly, the pressure is preferably applied to the stud elements 80, which in particular acts in the area of the respective heat transfer material 34 or heat conducting pad.

Due to the recesses 82 provided in the respective guide rail 78, the stud elements 80 can move comparatively far towards the cooling device 26 together with the entire circuit board unit 12 when the spring elements 84 apply the pressure illustrated by the arrows 86 to the stud elements 80.

When the stud elements 80 are received in the recesses 82 formed in the manner of locking depressions, thus, the coupling of the respective circuit board unit 12, 14, 16, 18 to the rear circuit board 74 via the respective connecting element 76 is preferably also established. In this mounting position or installation position in the housing 22 (not shown in FIG. 4), the circuit board unit 12 can be cooled by means of the cooling device 26, which is passed by the cooling fluid preferably formed as a liquid coolant. Herein, the heat transfer material 34 ensures the good thermal coupling of the respective circuit board unit 12 to the cooling device 26.

In FIG. 5, it is illustrated how the spring elements 84 preferably fixed to the housing 22 can apply the pressure illustrated by the arrows 86 to the stud elements 80. Accordingly, the respective spring element 84 can comprise a leg 88 oriented inclined in the installation position of the respective spring element 84. The respective stud element 80 gets into abutment with the leg 88, when the circuit board unit 12 is introduced into the housing 22 along the guide rails 78 in the mounting direction 20. This first leg 88 applies the respective stud element 80 with the pressure acting towards the cooling device 26 due to the introduction of the circuit board unit 12 into the housing 22 along the guide rail 78.

In particular, the pressure can effect compression of the heat transfer material 34, which is arranged between the top side 38 of the cooling device 26 and the outer wall 36 of the circuit board unit 12 according to FIG. 4 and FIG. 5. Preferably, the heat transfer material 34 is thus at least slightly compressible to achieve a particularly good thermal coupling of the circuit board unit 12 to the cooling device 26.

In the arrangement exemplarily and schematically shown in FIG. 5, each of the stud elements 80 is applied with the pressure acting towards the cooling device 26 by a spring element 84 acting on this stud element 80. Accordingly, a number of the spring elements 84 can in particular correspond to a number of the stud elements 80, which the respective circuit board unit 12 comprises.

According to FIG. 6, the respective spring element 84 can each include a further leg 92 for example forming a step 90. By means of this further or second leg 92, the respective spring element 84 can be fixed to the housing 22 in a manner presently not shown in more detail.

For example, the leg 92 comprising the step 90 can extend substantially parallel to the vertical direction z of the housing 22 in the arrangement on the or in the housing 22. In a lower end area of the second leg 92 in vertical direction z of the spring element 84, the second leg 92 can transition into the first leg 88, for example in the area of a bend 94 of the spring element 84, U-shaped in cross-section, wherein the first leg 88 applies the stud element 80 with the pressure.

However, the respective spring element 84 can also have a shape other than that exemplarily shown in FIG. 5 and in FIG. 6.

1. A control device arrangement comprising:
a housing, in which at least one circuit board unit and at least one cooling device are arranged,
wherein the at least one cooling device is supplied with a cooling fluid in the cooling operation and is formed for dissipating heat from the at least one circuit board unit, and
wherein the at least one circuit board unit is thermally coupled to the at least one cooling device by a heat transfer material,
wherein the at least one circuit board unit comprises:
an outer wall facing the at least one cooling device, in which at least one recess is formed,
wherein the heat transfer material is arranged in the at least one recess,
wherein the heat transfer material formed as a heat conducting paste is introduced into the at least one recess via an inlet opening, which is accessible from a narrow side of the at least one circuit board unit in an installation position of the at least one circuit board unit in the housing.

2. (canceled)

3. The control device arrangement according to claim 1,
wherein the at least one recess is formed as a channel system, which includes at least one channel section, which is connected to at least one basin area of the channel system,
wherein the at least one basin area has a larger width than the at least one channel section of the channel system.

4. The control device arrangement according to claim 3,
wherein the channel system includes a plurality of basin areas having a larger depth than the at least one channel section and/or depths different from each other,
wherein the basin areas are connected to each other via respective channel sections.

5. The control device arrangement according to claim 4,
wherein the basin areas are formed in sections of the at least one circuit board unit, in which more heat is released in the operation of the at least one circuit board unit than in areas of the at least one circuit board unit adjoining to the sections.

6. The control device arrangement according to claim 3,
wherein the channel system comprises:
at least one air outlet opening opening into a narrow side of the at least one circuit board unit,
wherein in a state, in which the at least one circuit board unit and the at least one cooling device are arranged in the housing of the control device arrangement, expelling of air out of the channel system via the at least one air outlet opening can be effected due to introduction of the heat transfer material into the channel system.

7. The control device arrangement according to claim 1,
wherein the at least one circuit board unit comprises:
a first area with a first thickness; and
a second area with a second thickness,
wherein the second thickness is larger than the first thickness,
wherein the at least one recess is formed in the first area, and
wherein an end side of the second area adjoining to the first area faces a narrow side of the at least one cooling device.

8. The control device arrangement according to claim 1, comprising:
at least two circuit board units, which are arranged mirror-imaged to each other in the housing,
wherein respective outer walls, comprising the at least one recess, of the at least two circuit board units arranged mirror-imaged face the same cooling device.

9. The control device arrangement according to claim 1,
comprising:
at least two cooling devices passed by the cooling fluid in the cooling operation, which are formed as cooling plates, arranged in the housing,
wherein a respective cooling plate is received between two circuit board units in a sandwich-like construction.

10. The control device arrangement according to claim 1,
wherein circuit board units arranged above each other in a vertical direction of the housing are connected to a further circuit board, which is arranged on a rear side of the housing, by a respective connecting element,
wherein the rear side is opposing a front-side access opening of the housing.

11. The control device arrangement according to claim 1,
wherein the at least one circuit board unit is applied with a pressure directed towards the at least one cooling device by at least one spring element,
wherein the pressure acts in the area of the heat transfer material formed as a heat conducting pad.

12. The control device arrangement according to claim 1,
wherein the circuit board unit comprises at least one stud element, which cooperates with a guide rail provided on the side of the housing,
wherein the at least one stud element is guided along the guide rail in introducing the circuit board unit into the housing.

13. The control device arrangement according to claim 12,
wherein the at least one stud element is applied with the pressure by the spring element, wherein the guide rail comprises a recess formed towards the at least one cooling device in the area of a target position of the at least one stud element, and wherein the at least one stud element is received in the recess.

14. The control device arrangement according to claim 13,
wherein the at least one spring element is fixed to the housing and includes a leg, which applies the at least one stud element with the pressure acting towards the at least one cooling device due to the introduction of the at least one circuit board unit into the housing along the guide rail, and/or the at least one circuit board unit comprises a plurality of stud elements,
wherein each of the stud elements is applied with the pressure acting towards the cooling device by a spring element acting on it.

15. A method for producing a control device arrangement, in which at least one circuit board unit and at least one cooling device are arranged in a housing of the control device arrangement, the method comprising:
supplying the at least one cooling device with a cooling fluid in the cooling operation and is formed for dissipating heat from the at least one circuit board unit, and
wherein the at least one circuit board unit is thermally coupled to the at least one cooling device by a heat transfer material,
wherein the at least one circuit board unit comprises an outer wall facing the at least one cooling device, in which at least one recess is formed,
wherein the heat transfer material is arranged in the at least one recess, while the at least one circuit board unit and the at least one cooling device are arranged in the housing,
introducing the heat transfer material formed as a heat conducting paste into the at least one recess via an inlet opening, which is accessible from a narrow side of the at least one circuit board unit in an installation position of the at least one circuit board unit in the housing.
